(19) United States
(12) Patent Application Publication
(10) Pub. No.: US 2026/0177615 A1
(43) Pub. Date: Jun. 25, 2026

(54) Matrix Switching Workflow in a Test System for Device Testing

(71) Applicant: NATIONAL INSTRUMENTS CORPORATION, Austin, TX (US)

(72) Inventors: Kosta Ilic, Austin, TX (US); Yaoming Ren, Shanghai (CN); Jason Wong, Austin, TX (US); Nestor Gomez, Cedar Park, TX (US)

(21) Appl. No.: 18/833,810

(22) PCT Filed: Jul. 28, 2023
(86) PCT No.: PCT/CN2023/109820

§ 371 Date: Jul. 26, 2024

(51) Int. Cl. G01R 31/3187

(52) U.S. Cl. CPC G01R 31/3187

(57) ABSTRACT

A matrix switching workflow allows for extending the virtual device configuration associated with a given single (test) site to multiple (test) sites, and expanding use of a single functional test program/sequence from a single site to multiple sites. Virtual device and connection support in a pin map editor enables mapping between switched instrument channels and switched device under test (DUT) pins on multiple sites, eliminating additional editing work. A switched channels section in a front test program design panel may list fully qualified channel connections to pins configured to a matrix switch. Configurations may be exported based on pin names and not based on the switch channel connection so that the configuration may be applied to switched instrument channels based on the specified pins. In order to avoid entering route/route-group names in the pin map, a specific route/route-group naming scheme may be used.

### BACKGROUND OF THE INVENTION

### Field of the Invention

This invention relates to measurement, data acquisition, and test systems, including a matrix switching workflow in test systems for device testing.

### Description of the Related Art

Measurement systems are oftentimes used to perform a variety of functions, including measurement of physical phenomena, measurement of certain characteristics or operating parameters of a unit under test (UUT) or device under test (DUT), testing and analysis of physical phenomena, process monitoring and control, control of mechanical or electrical machinery, data logging, laboratory research, and analytical chemistry, to name a few examples.

Test engineers responsible for electronic component testing oftentimes need a way to drive, or generate test signals and measure signals of interest based on the test signals, by using specific channels on specific instruments. In some cases, users intend to connect those instrument channels to locations of interest using switches. In case of parallel multi-site test systems, test sequences are expected not to be specific to a given site or any particular test sites for greater flexibility and test consistency. It would be desirable to expand the number of sites without making site-specific changes to any given test sequence.

Other corresponding issues related to the prior art will become apparent to one skilled in the art after comparing such prior art with the present invention as described herein.

### SUMMARY OF THE INVENTION

Embodiments are presented herein of a system and method for efficient matrix switching workflow in test systems. In some embodiments, a matrix switching workflow may allow for extending the virtual device configuration associated with a given single (test) site to multiple (test) sites, and expanding use of a single functional test program/sequence from a single site to multiple sites. Virtual device and connection support in a pin map editor may enable mapping between switched-instrument channels and switched-device-under-test (DUT) pins on multiple sites, eliminating additional editing work. A switched-channels section in a front test program design panel may list fully qualified channel connections to pins configured in a matrix switch. Configurations may be exported based on pin names instead of being exported based on the switch channel connection such that the configuration may be applied to switched-instrument channels based on the specified pins. To avoid having to enter route/route-group names in the pin map, a specific route/route-group naming scheme may be used.

In some embodiments, a method may allow for efficient testing of DUTs at multiple test sites. The method may include creating a pin map associated with one or more DUT pins and one or more instrument channels and one or more test sites. For each given DUT, given instrument channel, and given test site, the pin map may specify switches at a virtual device level, and may further specify a switched connection between the given DUT pin and the given instrument channel for the given test site through a corresponding virtual device. The method may further include creating virtual devices and routes/route-groups associated with the one or more DUT pins, the one or more instrument channels, and the one or more test sites, according to a specific naming convention that enables automatically associating used routes/route groups with selected test sites. The method may also include configuring switched instrument settings for switched DUT pins associated with the virtual devices and routes/route groups, and controlling switches for DUT testing according to the configured switched instrument settings. The method incorporates efficiently expanding a virtual device configuration associated with a given test site to multiple test sites and efficiently expanding testing from a single functional test program associated with the given test site to multiple test sites.

In some embodiments, a system may include a test system associated with one or more instruments and one or more switch matrixes, and may further include a test fixture associated with one or more DUTs respectively associated with one or more different test sites, with the test system configured to control the test fixture via the one or more switch matrixes according to switched-instrument settings. The switched-instrument settings may be configured for switched-DUT pins associated with virtual devices and routes/route-groups, with the virtual devices and routes/route-groups each associated with a respective switched connection between a given DUT pin and a given instrument channel at a given test site. Used routes/route-groups may be automatically associated with selected test sites of the one or more different test sites. This automatic association may be based on or derived as a benefit from a specific naming convention used for creating the virtual devices and routes/route-groups. The specific naming convention may include DUT-pin identification, test-site identification, and instrument-type identification. In one sense, the specific naming convention enables establishing a mapping between switched-instrument channels and switched-DUT pins across multiple test sites. In controlling the test fixture according to the switched-instrument settings, the test system may establish connectivity between an instrument channel and a DUT pin at a selected test site via a respective switch matrix of the one or more switch matrixes.

In some embodiments, a system may include one or more instruments, one or more switch matrixes coupled to the one or more instruments, one or more DUTs associated with one or more test sites and coupled to the switch matrixes, and control circuitry to establish connectivity between respective DUT pins and instrument channels via the one or more switch matrixes according to specified switched-instrument settings. The switched-instrument settings may be configured for switched-DUT pins associated with virtual devices and routes/route-groups, with the virtual devices and routes/route-groups each associated with a respective switched connection between a given DUT pin and a given instrument channel at a given test site. Used routes/route-groups may be automatically associated with selected test sites of the one or more test sites, for example based on a specific naming convention used for creating the virtual devices and routes/route-groups. The control circuitry may also execute one or more test programs corresponding to the established connectivity.

This Summary is intended to provide a brief overview of some of the subject matter described in this document. Accordingly, it will be appreciated that the above-described features are merely examples and should not be construed to narrow the scope or spirit of the subject matter described herein in any way. Other features, aspects, and advantages of the subject matter described herein will become apparent from the following Detailed Description, Figures, and Claims.

### BRIEF DESCRIPTION OF THE DRAWINGS

The foregoing, as well as other objects, features, and advantages of this invention may be more completely understood by reference to the following detailed description when read together with the accompanying drawings in which:

FIG. 1 shows an example diagram of a simplified overview of a test design toolkit for generating and executing test programs;

FIG. 2 shows an example system with a test system and test fixture, according to some embodiments;

FIG. 3 shows an example system diagram for illustrating a specific routes/route-groups naming scheme as it corresponds to various system components, according to some embodiments;

FIG. 4 shows an example system with instruments networked together, according to some embodiments; and

FIG. 5 shows an example flow diagram of an example method for testing devices at multiple test sites, according to some embodiments.

While the invention is susceptible to various modifications and alternative forms, specific embodiments thereof are shown by way of example in the drawings and will herein be described in detail. It should be understood, however, that the drawings and detailed description thereto are not intended to limit the invention to the particular form disclosed, but on the contrary, the intention is to cover all modifications, equivalents, and alternatives falling within the spirit and scope of the present invention as defined by the appended claims. Note, the headings are for organizational purposes only and are not meant to be used to limit or interpret the description or claims. Furthermore, note that the word “may” is used throughout this application in a permissive sense (i.e., having the potential to, being able to), not a mandatory sense (i.e., must).” The term “include”, and derivations thereof, mean “including, but not limited to”. The term “coupled” means “directly or indirectly connected”.

### DETAILED DESCRIPTION OF THE EMBODIMENTS

### Terms

The following is a glossary of terms that may appear in the present disclosure:
Memory Medium—Any of various types of non-transitory memory devices or storage devices. The term “memory medium” is intended to include an installation medium, e.g., a CD-ROM, floppy disks, or tape device; a computer system memory or random access memory such as DRAM, DDR RAM, SRAM, EDO RAM, Rambus RAM, etc. ; a non-volatile memory such as a Flash, magnetic media, e.g., a hard drive, or optical storage; registers, or other similar types of memory elements, etc. The memory medium may comprise other types of non-transitory memory as well or combinations thereof. In addition, the memory medium may be located in a first computer system in which the programs are executed, or may be located in a second different computer system which connects to the first computer system over a network, such as the Internet. In the latter instance, the second computer system may provide program instructions to the first computer system for execution. The term “memory medium” may include two or more memory mediums which may reside in different locations, e.g., in different computer systems that are connected over a network. The memory medium may store program instructions (e.g., embodied as computer programs) that may be executed by one or more processors.
Computer System (or Computer)—any of various types of computing or processing systems, including a personal computer system (PC), mainframe computer system, workstation, network appliance, Internet appliance, personal digital assistant (PDA), television system, grid computing system, or other device or combinations of devices. In general, the term “computer system” may be broadly defined to encompass any device (or combination of devices) having at least one processor that executes instructions from a memory medium.
Processing Element (or Processor)—refers to various elements or combinations of elements that are capable of performing a function in a device, e.g., in a user equipment device or in a cellular network device. Processing elements may include, for example: processors and associated memory, portions or circuits of individual processor cores, entire processor cores, processor arrays, circuits such as an ASIC (Application Specific Integrated Circuit), programmable hardware elements such as a field programmable gate array (FPGA), as well any of various combinations of the above.
Configured to—Various components may be described as “configured to” perform a task or tasks. In such contexts, “configured to” is a broad recitation generally meaning “having structure that” performs the task or tasks during operation. As such, the component can be configured to perform the task even when the component is not currently performing that task (e.g., a set of electrical conductors may be configured to electrically connect a module to another module, even when the two modules are not connected). In some contexts, “configured to” may be a broad recitation of structure generally meaning “having circuitry that” performs the task or tasks during operation. As such, the component can be configured to perform the task even when the component is not currently on. In general, the circuitry that forms the structure corresponding to “configured to” may include hardware circuits.
DUT—Device Under Test
SMU—Source Measurement Unit—an instrument that combines a sourcing function and a measurement function on the same pin or connector. An SMU may source voltage and/or current and may simultaneously measure voltage and/or current.

Various components may be described as performing a task or tasks, for convenience in the description. Such descriptions should be interpreted as including the phrase “configured to.” Reciting a component that is configured to perform one or more tasks is expressly intended not to invoke 35 U.S.C. § 112, paragraph six, interpretation for that component.

### Multiplexers and Multiplexed Connections in a Pin Map

Electronic component testing typically involves the generation (or driving) and measurement of test signals of interest. This is oftentimes accomplished via the use of specific channels on specific instruments. In some cases, instrument channels are connected to locations of interest using switches. In case of parallel multi-site test systems, it is desirable to generate test sequences in a manner that is not specific to a given (test) site or sites. In other words, it is desirable to expand the number of (test) sites without having to make site-specific changes to previously generated test sequence(s).

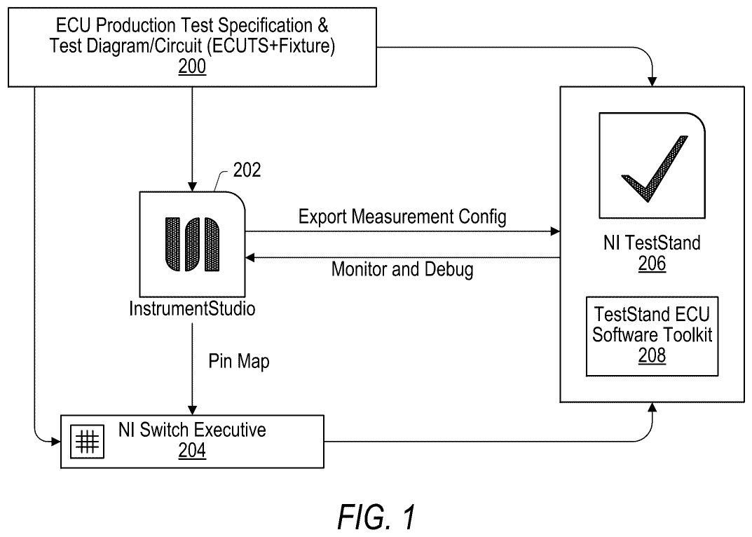

A multiplexed connection may define a connection between a single instrument channel and the same device under test (DUT) pin on multiple (test) sites. Various design tools may be used for generating the test vectors/sequences and test setups/programs/specification. One set of tools includes NI's Instrument Studio, Test Stand and Switch Executive tool set. FIG. 1 shows an exemplary diagram illustrating and overview for NI's Test Stand Electronic Control Unit (ECU) Toolkit. The illustrated system, or toolkit, includes four main components or tools used in generating a test program or test specification for DUT. Use of the various tools/components is further described below.

Currently, duplicate route/route group names need to be created in NI Switch Executive in pin map. The multiplexed connection does not support switching multiple instrument channels. To support the switches used to connect multiple instrument channels to multiple locations of interest, the switches need to be treated as multiple multiplexers, with each multiplexer used to switch a single instrument channel. Additionally, virtual/dummy pins need to be created in order to define the connections between the multiple instrument channels and locations of interest. Identical virtual devices are created on a per-site basis in Switch Executive. The virtual device configurations are then exported, and further adjusted in a text editor, then imported for other sites. In order to accomplish this, organized arrays of virtual devices in Test Stand are used to program relevant virtual devices indexing those arrays based on the site.

### Improved Matrix Switching Work Flow

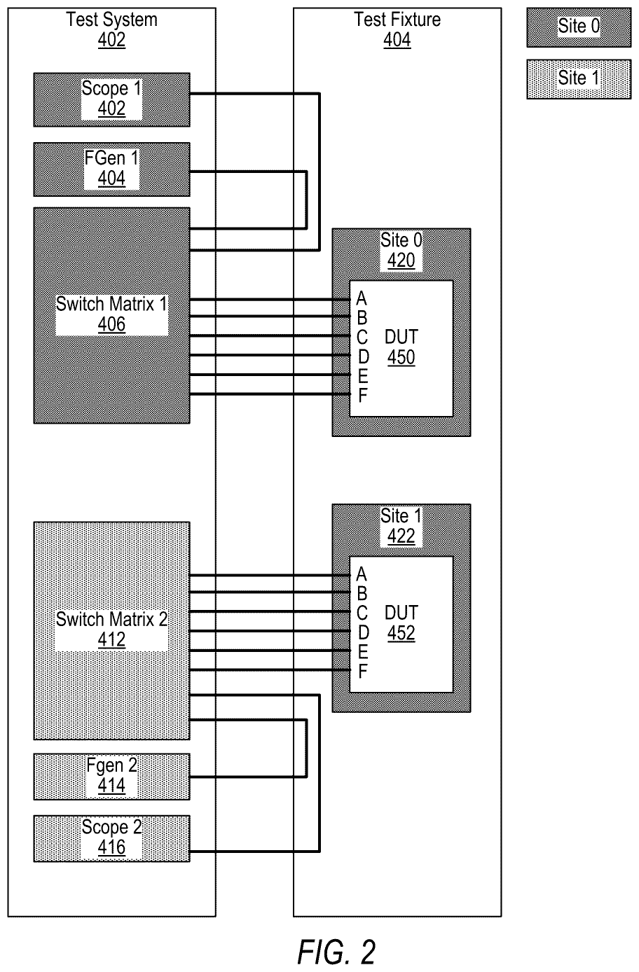

In some embodiments, and improved matrix switching workflow allows for expanding the number of test sites for given test setups or test sequences without having to make site-specific changes to the test setups/sequences. The improved workflow is described in the context of an exemplary system illustrated in FIG. 2. As shown in FIG. 2, the system may include a test system 402, a test fixture 404, and DUTs 450 and 452 situated at different test sites 420 and 422, respectively. Each DUT is shown featuring multiple ports A-F. Test system 402 may include a first test deck with function generator 404, measurement scope 402, and switch matrix 406 for test site 420, and a second test deck with function generator 414, measurement scope 416, and switch matrix 412 for test site 422.

In some embodiments, an improved matrix switching workflow may include the following procedures or steps (referencing the test tools shown in FIG. 1):
1) Creating a pin map, e.g., with a Pin Map Editor in Instrument Studio 202 or in Test Stand 206.
   a. The Pin map specifies switches at the Switch Executive 204 virtual device level.
   b. The Pin map specifies a switched connection between a DUT pin and an instrument channel for one site through a Switch Executive virtual device.
   c. Pin map contains no references to Switch Executive routes or route-groups.
2) Creating virtual devices and routes/route-groups in NI Switch Executive 204.
   a. Established naming conventions may be used for routes and route-groups to automatically tie or associate the routes and route-groups to select(ed) corresponding test sites, such that when connections are required to be made or broken, they take place at the appropriate corresponding test site.
3) Configuring the switched-instrument settings for the switched-DUT-pins in Instrument Studio 202, and then exporting the configuration to Test Stand 206
4) Controlling switches by using Switch Executive 204 step types in Test Stand 206.

In order to support the above described matrix switching workflow, additional elements be introduced in Pin Map Editor. In some embodiments, a virtual device element (e.g., Switch Executive virtual device) and connection support (e.g., Switch Executive connection support) may added in Pin Map Editor to establish a mapping between the switched-instrument channels and switched-DUT-pins on (or across) multiple sites.

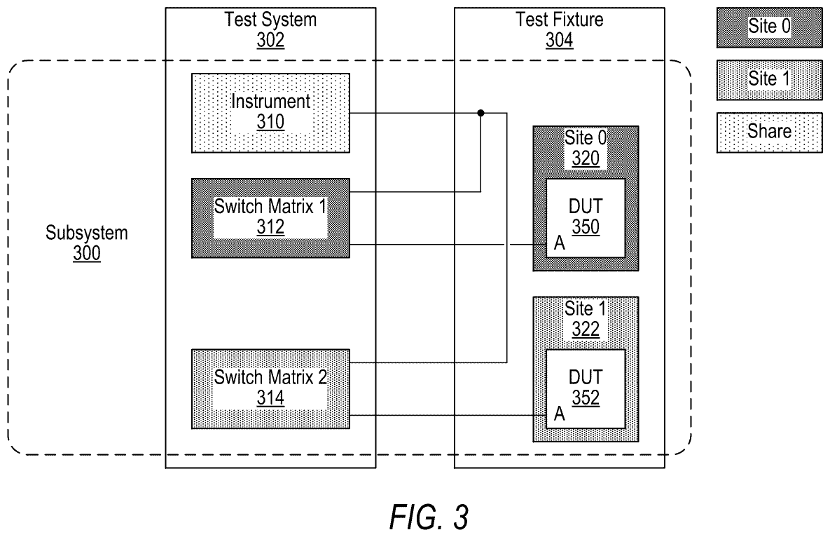

The above may be implemented in support of a variety of switching scenarios. Examples typical switching scenarios include:
Share an instrument channel with the same DUT pin on multiple sites through a switch. For example, in reference to FIG. 3, an instrument channel (of instrument 310) may be shared via switch matrices 312 and 314, respectively, across multiple sites (320 and 322), with the instrument channel coupled to the same DUT pin (e.g., pin A) for each respective DUT (350 and 352) at the given site where the DUT is located (320 and 322, respectively).
Share an instrument channel with multiple DUT pins on the same site through a switch. For example, in reference to FIG. 2, an instrument channel (from instruments 402, 404, 414, and/or 416) may be shared via switch matrix 406 or switch matrix 412, respectively, across multiple DUT pins (e.g., pin A and pin B, or pin A and pin B and pin C, etc.) at a given site where the DUT is located (420 or 452, respectively).
Share multiple instrument channels (e.g., from instruments 402, 404, 414, and/or 416) with a DUT pin through a switch. For example, in reference to FIG. 2, multiple instruments channels may be shared via switch matrix 406 or switch matrix 412, respectively, with a DUT pin (e.g., pin A or pin B or pin C, etc.) at a given site where the DUT is located (420 or 452). In this case, the switch matrix may switch between different instrument channels within the switch to provide a given instrument channel at a time to the same DUT pin at the given site.

To resolve the challenge of representing pins defined by Switch Executive connections, a new section named Switched Channels may be introduced in the soft front panel of Instrument Studio 202, residing next to the Pins section. This Switched Channels section may provide a list of fully qualified channel connections to pins configured in a matrix switch. An exported configuration may be generated based on pin names as opposed to being generated based on switch channel connections, which allows the configuration to be applied to switched instrument channels based on the specified pins. To avoid having to enter the route/route-group names in Pin Map, a specified route/route-group naming scheme may be used when creating routes/route-groups in NI Switch Executive 204.

To obtain the correct route/route-group required to access the switched DUT pin and the switched instrument channel, NI Switch Executive “step types” may be added in Test Stand 206. A designed step may thereby return site-based NI Switch Executive virtual device sessions, switch routes, and new Pin Map object references to access a switched pin and a switched instrument channel for each site.

The improved workflow allows for extending the Switch Executive virtual device configuration associated with a single site to multiple sites, thereby expanding the use of a single functional test program/sequence from a single site to multiple sites.

### Matrix Switching Work Flow Example

Based on the above, a test program may be generated such that a single functional test program/sequence may be used over multiple sites without requiring additional editing work. In some embodiments, a Switch Executive instrument may be inserted in the Pin Map editor, and a Switch Executive Connection may be defined such that it specifies a switched connection between a DUT pin and instrument channel for one site through a Switch Executive virtual device. A specific Switch Executive virtual device route/route-group naming scheme may be used to allow for expansion of the functional test program from a single site to multiple sites. In some embodiments, the naming scheme may be:
<Pin Name>_Index#-<Instrument Type Id>
   where:
“Pin Name” is the DUT pin defined in the Pin Map file through Pin Map Editor;
“Index #”′ is the index of a site included in a site list associated with a subsystem; and
“Instrument Type Id” is the type identification for the instrument. The “type id” may be a constant string.

FIG. 3 shows an exemplary system setup for illustrating the correspondence between the specific naming scheme and certain system components. The system in FIG. 3 may include a Test System 302 and Test Fixture 304. A single subsystem 300 may encompass Instrument 310, Switch Matrix 312, and Switch Matrix 314 on the Test System side, and DUT 350 (at Site 320) and DUT 352 (at Site 322) on the Test Fixture side. In reference to FIG. 3 by way of example, Pin A of DUT 350 and Pin A of DUT 352 are both contained within single Subsystem 300. The site list associated with Subsystem 300 is {Site 0, Site 1}. The site list may be ordered by site. Accordingly, in the exemplary set up in FIG. 3, Site 0 is associated with a virtual device with Switch Matrix 1 (Switch Matrix 312) and a route/route-group named “A_0-Instrument”, where ‘A’ is the pin name, ‘0’ is the site ID, and ‘Instrument’ is the instrument type ID identifying the instrument (type). Site 1 is associated with a virtual device with Switch Matrix 2 (Switch Matrix 314) and a route/route-group named “A_1-Instrument”, where ‘A’ is the pin name, ‘1’ is the site ID, and ‘Instrument’ is the instrument type ID identifying the instrument (type).

Using the above naming scheme, referencing the tools shown in FIG. 1, a test program (sequence) may be generated, with the most important steps indicated as follows. A Pin Session may be initiated to initialize the Pin Map context with driver session for instruments. Next, an Open Session may be initiated to create sessions for all NI Executive virtual devices in the Pin Map Context and store the created sessions in the Pin Map Context. An ECU Multi Test or ECU Action step may be used with its module adapter configured as Sequence as the top-level step.

An illustrative sequence called by the top-level ECU Multi Test step may be as follows:
The Apply Pin Configuration step is called to reset the instruments to their default settings and configure the selected pins with pin settings from a corresponding Measurement Configuration file.
For each pin, the Switch Executive ‘Pin to Sessions’ step is called to get the site-based route/route group names and virtual device sessions for the switched pin and the switched instrument type. For each site for the given pin:
   The Switch Executive ‘Connect’ step is called to build the connections between the switched pin and the switched instrument channel on the current site.
   The appropriate ‘Measurement Control group’ step types are called for the used instrument to read and publish measurements to the top-level ECU ‘Multi Test Sequence Call’ step.
   The Switch Executive ‘Disconnect’ step is called to disconnect the switched pin and the switched instrument channel on the current site.

A process cleanup sequence may include calling the “Close Pin Sessions'step to close all instruments driver sessions initialized by the ‘Create Pin Sessions’ step, and calling the Switch Executive ”Close Sessions'step to close all Switch Executive virtual device sessions in the Pin Map Context. In this manner, the Switch Executive virtual device configuration associated with one site may be easily expanded to multiple sites, and testing may be expanded to using a single functional test program for multiple sites.

### Example Method

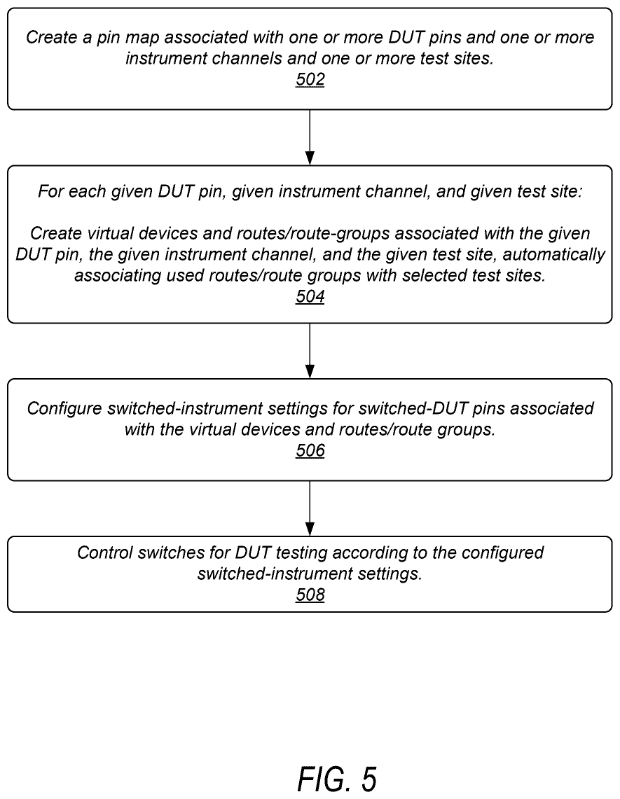

FIG. 5 shows an example flow diagram for efficiently testing devices under test (DUTs) at multiple test sites. The method may include creating a pin map associated with one or more DUT pins and one or more instrument channels and one or more test sites (502). For each given DUT, given instrument channel, and given test site, the pin map may specify switches at a virtual device level, and may further specify a switched connection between the given DUT pin and the given instrument channel for the given test site through a corresponding virtual device. The method may further include creating virtual devices and routes/route-groups associated with the one or more DUT pins, the one or more instrument channels, and the one or more test sites, according to a specific naming convention that enables automatically associating used routes/route groups with selected test sites (504). The method may also include configuring switched instrument settings for switched DUT pins associated with the virtual devices and routes/route groups (506), and controlling switches for DUT testing according to the configured switched instrument settings (508). The method incorporates efficiently expanding a virtual device configuration associated with a given test site to multiple test sites and efficiently expanding testing from a single functional test program associated with the given test site to multiple test sites.

### Example Measurement/Instrument System

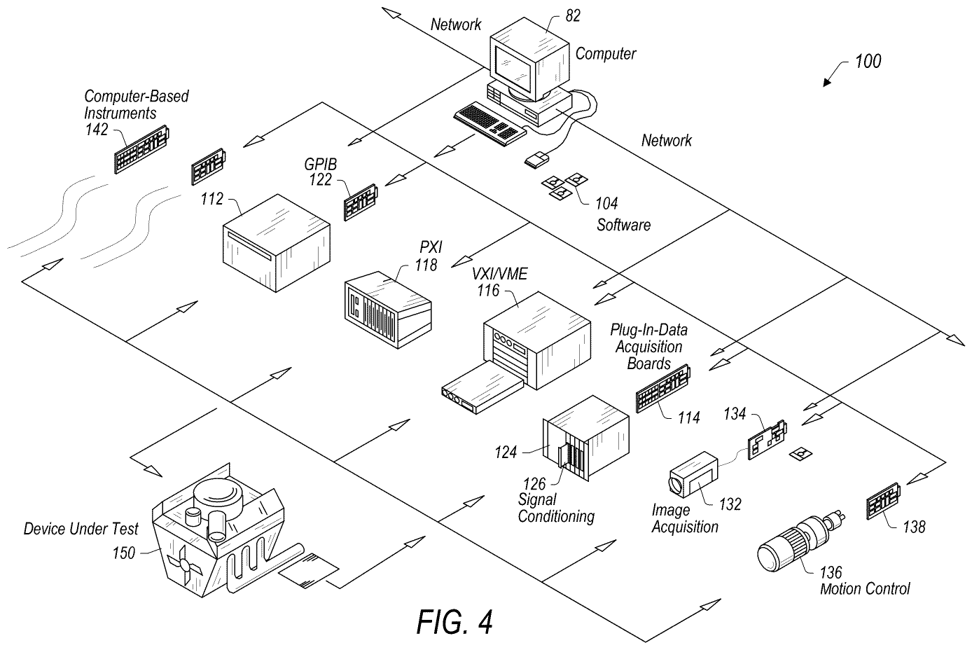

FIG. 4 illustrates an exemplary system 100 which may include and implement test program generation including the matrix switching workflow and subsequent DUT testing according to various embodiments disclosed herein. System 100 comprises a host computer 82 which may couple to one or more instruments configured to perform a variety of functions using system level health monitoring implemented according to various embodiments of the present invention. Host computer 82 may comprise a CPU, a display screen, memory, and one or more input devices such as a mouse or keyboard as shown. Computer 82 may operate with one or more instruments to analyze, measure, or control a unit under test (UUT) or process 150. The one or more instruments may include a GPIB instrument 112 and associated GPIB interface card 122, a data acquisition board 114 inserted into or otherwise coupled with chassis 124 with associated signal conditioning circuitry 126, a VXI instrument 116, a PXI instrument 118, a video device or camera 132 and associated image acquisition (or machine vision) card 134, a motion control device 136 and associated motion control interface card 138, and/or one or more computer based instrument cards 142, among other types of devices. The computer system may couple to and operate with one or more of these instruments. In some embodiments, the computer system may be coupled to one or more of these instruments via a network connection, such as an Ethernet connection, for example, which may facilitate running a high-level synchronization protocol between the computer system and the coupled instruments. The instruments may be coupled to the unit under test (DUT) or process 150, or may be coupled to receive field signals, typically generated by transducers. System 100 may be used in a data acquisition and control applications, in a test and measurement application, an image processing or machine vision application, a process control application, a man-machine interface application, a simulation application, or a hardware-in-the-loop validation application, among others. In some embodiments, at least some components of system 100, for example, PXI instrument 118, may include multiple instruments, positioned in a rack enclosure, for example, and connected or coupled to a mass interconnect, which may in turn connect or couple the instrument to other device(s) or equipment as desired, as disclosed herein. For example, PXI instrument 118 may include some or all components of an instrument and/or test system as disclosed herein to perform various desired functions autonomously or under partial or full control of host computer 82. Additionally, host computer 82 may be configured to implement at least the toolkit shown in FIG. 1.

Although the embodiments above have been described in considerable detail, other versions are possible. Numerous variations and modifications will become apparent to those skilled in the art once the above disclosure is fully appreciated. It is intended that the following claims be interpreted to embrace all such variations and modifications. Note the section headings used herein are for organizational purposes only and are not meant to limit the description provided herein or the claims attached hereto.

We claim:

1. A method for testing devices under test (DUTs) at multiple test sites, the method comprising:
creating a pin map associated with one or more DUT pins and one or more instrument channels and one or more test sites, wherein for each given DUT, given instrument channel, and given test site, the pin map
specifies switches at a virtual device level, and
specifies a switched connection between the given DUT pin and the given instrument channel for the given test site through a corresponding virtual device;
creating virtual devices and routes/route-groups associated with the one or more DUT pins, the one or more instrument channels, and the one or more test sites, automatically associating used routes/route-groups with selected test sites;
configuring switched-instrument settings for switched-DUT-pins associated with the virtual devices and routes/route-groups; and
controlling switches for DUT testing according to the configured switched-instrument settings.

2. The method of claim 1, wherein automatically associating the used routes/route-groups with the selected test sites is accomplished via creating the virtual devices and routes/route-groups according to a specific naming convention.

3. The method of claim 2, wherein the specific naming convention includes DUT-pin identification, test-site identification, and instrument-type identification.

4. The method of claim 2, wherein the specific naming convention enables establishing a mapping between switched-instrument channels and switched-DUT pins across multiple test sites.

5. The method of claim 1, wherein controlling the switches comprises establishing connectivity between an instrument channel and a DUT pin at a selected test site.

6. A system comprising:
a test system associated with one or more instruments and one or more switch matrixes; and
a test fixture associated with one or more devices under test (DUTs) respectively associated with one or more different test sites, wherein the test system is configured to control the test fixture via the one or more switch matrixes according to switched-instrument settings;
wherein the switched-instrument settings are configured for switched-DUT pins associated with virtual devices and routes/route-groups, wherein the virtual devices and routes/route-groups are each associated with a respective switched connection between a given DUT pin and a given instrument channel at a given test site; and
wherein used routes/route-groups are automatically associated with selected test sites of the one or more different test sites.

7. The system of claim 6, wherein the used routes/route-groups are automatically associated with selected test sites of the one or more different test sites based on a specific naming convention used for creating the virtual devices and routes/route-groups.

8. The system of claim 7, wherein the specific naming convention includes DUT-pin identification, test-site identification, and instrument-type identification.

9. The system of claim 7, wherein the specific naming convention enables establishing a mapping between switched-instrument channels and switched-DUT pins across multiple test sites.

10. The system of claim 6, wherein to control the test fixture according to switched-instrument settings, the test system is configured to establish connectivity between an instrument channel and a DUT pin at a selected test site via a respective switch matrix of the one or more switch matrixes.

11. A system comprising:
one or more instruments;
one or more switch matrixes coupled to the one or more instruments;
one or more devices under test (DUTs) associated with one or more test sites and coupled to the switch matrixes; and
control circuitry configured to establish connectivity between respective DUT pins and instrument channels via the one or more switch matrixes according to specified switched-instrument settings;
wherein the switched-instrument settings are configured for switched-DUT pins associated with virtual devices and routes/route-groups, wherein the virtual devices and routes/route-groups are each associated with a respective switched connection between a given DUT pin and a given instrument channel at a given test site; and
wherein used routes/route-groups are automatically associated with selected test sites of the one or more test sites.

12. The system of claim 11, wherein the control circuitry is further configured to execute one or more test programs corresponding to the established connectivity.

13. The system of claim 11, wherein the used routes/route-groups are automatically associated with selected test sites of the one or more different test sites based on a specific naming convention used for creating the virtual devices and routes/route-groups.

14. The system of claim 13, wherein the specific naming convention includes DUT-pin identification, test-site identification, and instrument-type identification.

15. The system of claim 13, wherein the specific naming convention enables establishing a mapping between switched-instrument channels and switched-DUT pins across multiple test sites.
